(19) United States
(12) Patent Application Publication
(10) Pub. No.: US 2002/0038871 A1
(43) Pub. Date: Apr. 4, 2002

(54) Method and apparatus for making a load cell

(75) Inventor: Michael Allan Dingman, Utica, MI (US)

Correspondence Address: LAURA M. SLENZAK, SIEMENS CORPORATION, 186 WOOD AVENUE SOUTH, ISELIN, NJ, 08830, US

(73) Assignee: Siemens Automotive Corporation

(21) Appl. No.: 09/888,904

(22) Filed: Jun. 25, 2001

Related U.S. Application Data
(60) Provisional application No. 60/230,139, filed on Oct. 2, 2000.

(51) Int. Cl. H01L 21/00

(52) U.S. Cl. 257/99; 438/7; 438/57; 257/232

(57) ABSTRACT

A unique method and apparatus for making a load cell provides a sensor, circuit board, and connector that are integrally formed as one piece by using a photo-imaging process. A conductive material is layered on a non-conductive material in a predetermined pattern including a sensor portion, a circuit board portion, and a conductive path connecting the sensor and circuit board portions. A photo-reactive film is applied to the conductive material and portions of the photo-reactive film are exposed to a light source. The light source is applied through a negative that defines the sensor, circuit board, and conductive path dimensions. The portions of the film that are exposed to the light cause bonding between the conductive and non-conductive materials and integrally form the sensor, circuit board, and conductive path as one piece. The unexposed film and the associated underlying conductive material are removed by etching.

### RELATED APPLICATIONS

This application claims priority to provisional application 60/230,139 filed on Oct. 2, 2000.

### BACKGROUND OF THE INVENTION

1. Field of the Invention

This invention relates to a method and apparatus for making a load cell. Specifically, the load cell includes a sensor portion electrically connected to a circuit board portion where the sensor and circuit board portions are formed during the same process.

2. Related Art

Load cells are used to measure weight forces exerted against the cells. Load cells can be used in various applications and are often used to determine seat occupant weight. The load cells are mounted to a seat structure, such as a seat bottom, and are used to measure the weight force exerted against the seat bottom by the seat occupant.

Current load cells are made by attaching a sensor, such as a strain gage, to a mounting surface. Then wires or flex cables are attached to pads on the strain gage. The opposite ends of the wires or flex cables are attached to electronics, typically a circuit board assembly. Separate electrical connections must be made to interconnect the gage, the wires or flex cables, and the electronics, which is a time consuming and difficult process. Another disadvantage with this process is that reliability of the gage is affected because of the possibility of failure at each connection site.

Thus, it is desirable to have a method and apparatus for making a load cell that eliminates the need for separate electrical connections between the sensor, electronics, and wires or flex cables and which significantly reduces manufacturing time and cost in addition to overcoming the above referenced deficiencies with prior art systems.

### SUMMARY OF THE INVENTION

The subject invention includes a method and apparatus for making a load cell having a sensor, circuit board, and connector formed as a single piece. The sensor, circuit board, and connector are integrally formed as one piece by using photo-imaging process.

In the preferred embodiment, a subtractive photo-imaging process is used in which a layer of conductive material is applied to a layer of non-conductive material in a predetermined pattern including a sensor portion, a circuit board portion, and a connector portion extending between the sensor and circuit board portions. A photo-reactive film material is applied to the conductive material and portions of the photo-reactive material are exposed to light. The light is applied through a negative that defines the size, shape, etc. of the sensor, circuit board, and connector portions. The portions of the photo-reactive material that are exposed to the light react to form a bond between the conductive and non-conductive material. The un-exposed photo-reactive material and the associated underlying conductive material are then etched away to form the one-piece load cell.

In an alternate embodiment, an additive photo-imaging process is used in which a photo-reactive film material is applied to a non-conductive material. Portions of the film material are exposed to light via a negative in a predetermined pattern. The pattern defines areas on the non-conductive material that will accept conductive material. The conductive material is then bonded or added to the non-conductive material in the designated areas to form the load cell.

The conductive material is preferably a metal foil that includes a sensor portion, circuit board portion, and connector portion. In one embodiment, the circuit board portion is thicker than the sensor. The sensor is preferably a strain gage that is formed from the conductive material.

The subject invention provides a method and apparatus for making a load cell that eliminates the need for separate electrical connections between the sensor, electronics, and wires or flex cables, thus significantly improving reliability. These and other features of the present invention can be best understood from the following specification and drawings, the following of which is a brief description.

### BRIEF DESCRIPTION OF THE DRAWINGS

FIG. 1 is a schematic side view of the apparatus for making the load cell and incorporating the subject invention.

FIG. 2 is a schematic overhead view of a load cell manufactured according to the subject inventive method.

FIG. 3 is a flowchart of the preferred method.

FIG. 4 is a flowchart of an alternate method.

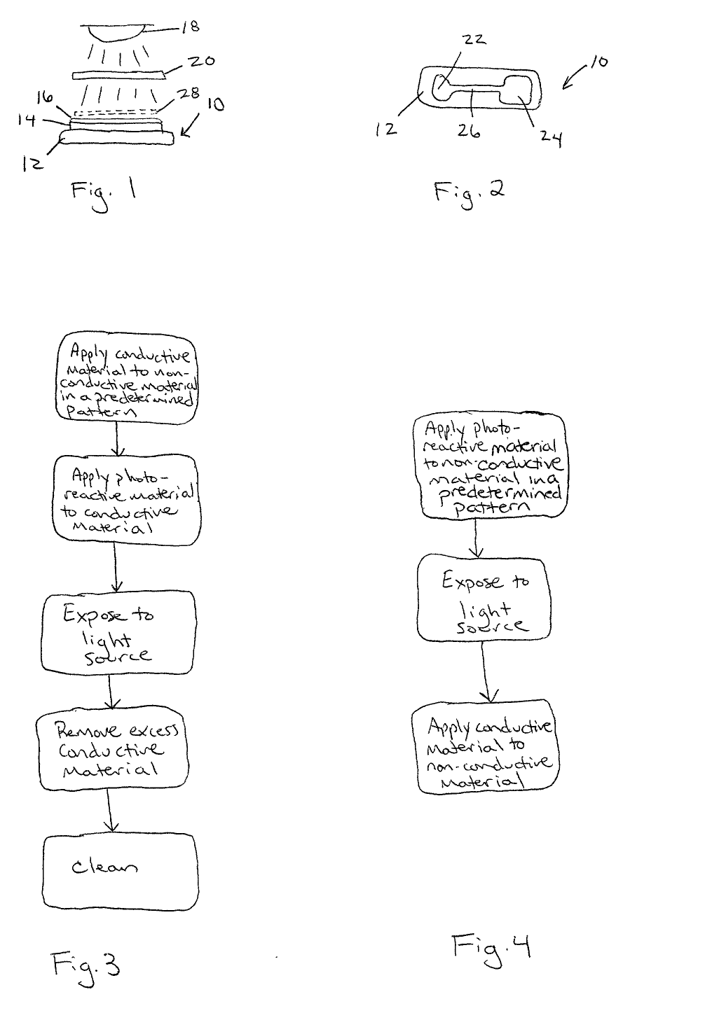

### DETAILED DESCRIPTION OF AN EXEMPLARY EMBODIMENT

The subject invention concerns a unique method for making a load cell. Load cells are used to measure weight forces exerted against the cells and can be used in various applications. Vehicle occupant classification systems are used to categorize occupants into predetermined classes such as adult, child, infant, etc. to provide better controls for safety systems such as airbags; and load cells are often used to determine seat occupant weight. Typically, the load cells are mounted to a seat structure, such as a seat bottom, and are used to measure the weight force exerted against the seat bottom by the seat occupant.

The subject invention includes a method and apparatus for making a load cell 10 having a sensor, circuit board, and connector formed as a single piece. The sensor, circuit board, and connector are integrally formed as one piece by using a photo-imaging process.

In the preferred embodiment, a subtractive photo-imaging process is utilized as described in FIG. 3. This process requires a non-conductive layer of material 12 and a conductive layer of material 14. The non-conductive layer of material 12 is preferably Mylar and the conductive layer of material 14 is preferably a thin copper foil, however, the conductive and non-conductive materials can be any similar known material in the art. The conductive layer of material 12 is overlaid on the non-conductive layer of material 14 in a predetermined pattern, i.e., the conductive material is applied only where electrical circuitry is needed. For example, the border of the non-conductive material 12 will remain uncovered because tooling is required to hold the non-conductive material in place during the process. Thus, the border should not be covered with conductive material, which will only later be removed as scrap.

Next, a photo-reactive material or film 16 is applied to the conductive layer of material 14. The film material 16 is a photoresist or other similar material known in the art. The film material 16 is applied thinly across the conductive layer 14 and reacts to exposure to a light source 18. The light source 18 is shown through an artwork negative 20, in a manner similar to that of black and white photography. The negative 20 defines a pattern that exposes certain portions of the conductive material 14 to the light source 18 and prevents exposure to other portions of the conductive material 14. The pattern defines the shape, size, etc. of a sensor portion 22, a circuit board portion 24, and a connector portion 26 forming a conductive path between the sensor 22 and circuit board 24 portions, see FIG. 2. The exposed portions become bonded to the non-conductive layer 12 and the non-exposed portions are subsequently removed with an etching process, which is well known. The etching process further defines the sensor 22, circuit board 24, and conductive path 26 and removes the excess conductive material 14. A cleaning film 28 is then applied to remove the excess photo-reactive film 16. Thus, the photo-imaging process allows the sensor 22, circuit board 24, and connector 26 to be integrally formed as one piece.

The above process is called a subtractive process because material is removed. In an alternate embodiment, an additive photo-imaging process is utilized, described in FIG. 4. In this process, a photo-reactive material 16 is applied directly to the non-conductive layer of material 12 in a predetermined pattern including sensor portion 22 and circuit board portion 24. The photo-reactive material 16 is exposed to the light source 18 through the negative 20 causing predetermined areas to react to the light. Only these reactive areas will accept conductive material/plating. Thus, after exposure to the light, the conductive layer of material 14 is added to the predetermined areas on the non-conductive layer of material 12 to form the one piece load cell 10 including the sensor portion 22, circuit board portion 24, and interconnecting conductive path portion 26.

The sensor 22 is preferably a strain gage, the operation of which is well known in the art and will not be discussed in detail. The circuit board is preferably a printed circuit board (PCB) the operation of which is also well known. The conductive layer of material 14 is used to form both the strain gage and PCB. As discussed above, the preferred conductive material is a thin copper foil. In the preferred embodiment, the strain gage is made from copper foil that is thinner than the copper foil that is used for the formation of the PCB. Typically, the foil for the strain gage is 0.001 inches thick and the foil for the PCB is 0.01 inches thick, however other thickness can be used. Using different foil thickness reduces cost, as the thinner foil is more expensive. The foils are laminated or joined together by methods known in the art, such as welding.

It should be understood that either the additive or subtractive photo-imaging process could be used to form the load cell 10. Preferably the sensor portion 22, circuit board portion 24, and connector portion 26 are all formed as a single piece, however, just the sensor 22 or circuit board 24 portions could be integrally formed with the connector portion 26 with the remaining portion of the sensor 22 or circuit board 24 being connected in the known manner.

The subject method and apparatus for making a load cell eliminates the need for separate electrical connections between the sensor, electronics, and connector portions, significantly reduces manufacturing time and cost, and improves reliability.

Although a preferred embodiment of this invention has been disclosed, it should be understood that a worker of ordinary skill in the art would recognize many modifications come within the scope of this invention. For that reason, the following claims should be studied to determine the true scope and content of this invention.

I claim:

1. A method for making a load cell having a sensor portion and a circuit board portion comprising the steps of:
(a) providing an assembly including a conductive material member and a non-conductive material member; and
(b) applying a photo-imaging process to one of the conductive or non-conductive material members to form a conductive path between the sensor portion and the circuit board portion.

2. The method according to claim 1 wherein the photo-imaging process is an additive process including the steps of applying a photo-reactive film to the non-conductive material member, exposing the film to a light source to produce a predetermined pattern for accepting the conductive material member, and adding the conductive material member to the pattern to from the load cell.

3. The method according to claim 1 wherein the photo-imaging process is a subtractive process including the steps of laying the conductive material on the non-conductive material in a predetermined pattern, applying a photo-reactive film to the conductive material, exposing portions of the film to a light source to define first portions that are exposed to light and second portions that are not exposed to light wherein the first portions bond the conductive material member to the non-conductive material member and the second portions are non-reactive, and etching the second portions to remove non-bonded conductive material.

4. The method according to claim 3 including the step of applying a cleaning film to the conductive and non-conductive material members to remove any remaining photo-reactive film.

5. The method according to claim 1 including forming the sensor portion, conductive path, and circuit board portion as one piece with the photo-imaging process.

6. The method according to claim 5 wherein the conductive material member is formed from a metal foil having a first portion that forms the sensor portion and a second portion that forms the circuit board portion.

7. The method according to claim 6 wherein the first portion is thinner than the second portion.

8. The method according to claim 7 wherein the first portion is approximately 0.001 inches thick and the second portion is approximately 0.01 inches thick.

9. A method for making a load cell having a sensor portion and a circuit board portion comprising the steps of:
(a) applying a layer of conductive material over a layer of non-conductive material in a predetermined pattern including a sensor portion, a circuit board portion, and a conductive path connecting the sensor and circuit board portions;
(b) applying a photo-reactive film to the conductive material;
(c) exposing portions of the photo-reactive film to a light source to bond the conductive material to the non-conductive material to integrally form the sensor portion, the circuit board portion, and the conductive path as one piece.

10. The method according to claim 9 wherein the light source is applied through a negative to define exposed portions of the photo-reactive film in which the conductive material is bonded to the non-conductive material and non-exposed portions of the photo-reactive film in which the conductive material is not bonded to the non-conductive material and including the step of removing the non-exposed portions of the photo-reactive film and the associated conductive material underneath the non-exposed portions.

11. The method according to claim 10 including the step of applying a cleaning material to the conductive and non-conductive materials to remove any remaining photo-reactive film.

12. The method according to claim 10 wherein the negative defines a load cell pattern including the sensor portion, the circuit board portion, and the conductive path.

13. The method according to claim 9 wherein the conductive material is comprised of a metal foil with the circuit board portion having a greater thickness than the sensor portion.

14. A load cell comprising:
a non-conductive layer; and
a conductive layer overlaid on said non-conductive layer and including a sensor, a circuit board member, and a connector extending from said sensor to said circuit board to transmit electrical signals from said sensor to said circuit board wherein at least one of said sensor or circuit board is integrally formed as one piece with said connector.

15. A load cell according to claim 14 wherein said conductive layer is bonded to said non-conductive layer via a photo-imaging process.

16. A load cell according to claim 15 wherein said conductive layer is a metallic foil having a sensor portion having a first thickness and a circuit board portion having a second thickness that is greater than the first thickness.

17. A load cell according to claim 16 wherein said first thickness is approximately 0.001 inches and said second thickness is approximately 0.01 inches.

18. A load cell according to claim 14 wherein said sensor, circuit board, and connector are integrally formed as one piece.
